(19) United States
(12) Patent Application Publication
(10) Pub. No.: US 2006/0105525 A1
(43) Pub. Date: May 18, 2006

(54) Method for forming non-volatile memory device

(75) Inventors: Hong-Suk Kim, Yongin-si (KR); Hyun Park, Hwaseong-si (KR); Mun-Jun Kim, Suwon-si (KR); Chang-Seob Kim, Gwangju-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/280,758

(22) Filed: Nov. 15, 2005

(30) Foreign Application Priority Data
Nov. 16, 2004 (KR) 10-2004-0093651

(51) Int. Cl. H01L 21/336

(52) U.S. Cl. 438/257

(57) ABSTRACT

A method for forming a non-volatile memory device is provided. According to the method, a device isolation layer defining an active region is formed on the device isolation layer. An upper surface of the device isolation layer is formed higher than a surface of the substrate to form a gap region surrounded by the upper portion of the device isolation layer. A tunnel insulation layer is formed on the active region, and a floating gate layer is formed on an entire surface of the substrate. The floating gate layer is reflowed by performing a hydrogen annealing to fill a gap region with the reflowed floating gate layer. The reflowed floating gate layer is planarized until the device isolation layer is exposed to form a floating gate pattern.

### CROSS-REFERENCE TO RELATED APPLICATIONS

This U.S. non-provisional patent application claims priority under 35 U.S.C. § 119 of Korean Patent Application No. 2004-93651 filed on Nov. 16, 2004, the entire contents of which are hereby incorporated by reference.

### BACKGROUND OF THE INVENTION

The present invention relates to methods for forming semiconductor devices and more particularly, to a method for forming a non-volatile memory device.

Non-volatile memory devices hold stored data even if a power supply is interrupted. A representative example of the non-volatile memory devices is a flash memory device having a floating gate. As charges are stored in the electrically isolated floating gate or the charges are emitted, the data stored in a unit cell of the flash memory device is classified as either a logic “1” or a logic “0”.

In general, a flash memory cell has a stacked gate structure. The stacked gate structure refers to a stacked structure, in which a floating gate and a control gate electrode controlling various operations of a cell are sequentially stacked. The floating gate and the control gate electrode are sequentially stacked to realize a more highly integrated flash memory device.

In a conventional method for forming a flash memory cell having the stacked gate structure, a tunnel oxide and a silicon oxide are sequentially formed on an active region, and the silicon layer is patterned to form a floating gate pattern overlapped with the active region. Next, an oxide-nitride-oxide layer (referred to as “an ONO layer”, hereinafter) and a control gate conductive layer are sequentially formed, and the control gate conductive layer, the ONO layer and the floating gate pattern are successively patterned to form a floating gate and a control gate electrode, which are sequentially stacked. In this conventional method, the floating gate pattern is formed by a patterning process including a photolithography process, thereby requiring an overlapping margin between the floating gate pattern and the active region.

With increasing integration density of semiconductor devices, an overlapping margin between layers is gradually decreased. In accordance with this trend, an overlapping margin between the floating gate pattern and the active region is gradually decreased, as well. In general, as a plane area of an active region is a necessary element in determining a plane area of a flash memory cell, the plane area of the active region may be formed to have the minimum size according to a design rule. For this reason, an overlapping margin between the floating gate pattern and the active region may be further decreased.

In order to improve the overlapping margin between the floating gate pattern and the active region, a method for forming the floating gate pattern on the active region using a self-alignment approach has been suggested. According to this method, a gap region surrounded by an upper portion of a device isolation layer is formed on the active region using a self-alignment process, and the gap region is filled with a silicon layer. The silicon layer is planarized until the device isolation layer is exposed to form the floating gate pattern. According to this method, the floating gate pattern and the active region are self-aligned, thus a photolithography process is not required. Accordingly, the floating gate pattern and the active region can be freed from an overlapping problem.

However, in a case in which a flash memory device is formed with the above-described methods, problems may occur. That is, with an increasing trend requiring high integration of semiconductor devices, an aspect ratio of the gap region may be increased. Accordingly, if the gap region is filled with the silicon layer, a seam and/or a void may occur in the gap region. As the seam or the void may be included in a floating gate formed in a subsequent process, characteristics of a flash memory cell may be degraded and/or failure of the flash memory cell may occur.

A conventional method for minimizing the seam or the void will be described with reference to the accompanying drawings.

FIGS. 1 to 4 are cross-sectional views illustrating methods for forming a conventional flash memory device.

Referring to FIG. 1, a hard mask layer is formed on a substrate 1, and the hard mask layer and the substrate 1 are successively patterned to form a trench 3 defining an active region. A device isolation layer 4 filling the trench is formed. At this time, the device isolation layer 4 has a top surface in the same plane as a top surface of the patterned hard mask layer 2.

Referring to FIG. 2, the patterned hard mask layer 2 is removed to expose the active region. At this time, a gap region 15 from which the patterned hard mask layer 2 is removed is formed on the active region. Next, a tunnel oxide layer 5 is formed on the exposed active region, and the first silicon layer 6 filling a part of the gap region 15 is formed on an entire surface of the substrate 1. At this time, an aspect ratio of the empty region of the gap region 15 may be increased.

Referring to FIG. 3, wet etching is performed to isotropically etch the first silicon layer 6. Accordingly, an aspect ratio of the empty region of the gap region 15 is decreased. A second silicon layer 7 filling the gap region 15 is formed on the etched first silicon layer 6a. The etched first silicon layer 6a and the second silicon layer 7 constitute a floating gate layer 8.

Referring to FIG. 4, the floating gate layer 8 is planarized until the device isolation layer 4 is exposed to form a floating gate pattern 8a. The floating gate pattern 8a includes the first planarized silicon layer 6b and the second planarized silicon layer 7a.

According to the above described conventional forming method, the first silicon layer 6 is isotropically etched with the wet etching to decrease an aspect ratio with respect to the empty region of the gap region 15, and the second silicon layer 7 is formed to minimize a seam or a void in the gap region 15.

However, in the above-described conventional method, the first silicon layer 6 formed in the gap region 15 may be formed to have a slant sidewall due to a high aspect ratio of the gap region 15. In particular, an over line is formed on the upper sidewall of the gap region 15 to create a negative slant. The first silicon layer 6 is isotropically etched to form a slant sidewall of the etched first silicon layer 6a in the gap region 15. As a result, even if the second silicon layer 7 is formed, a seam and/or a void 9 may be formed in the gap region 15. Accordingly, as a floating gate (not shown) formed from the floating gate pattern 8a includes the seam and/or the void 9, characteristics of a flash memory cell may be degraded or failures of the flash memory cell may occur.

In addition, according to the above described conventional method, in order to form the floating gate layer 8, more than one wet etching process is required to be performed between processes for forming silicon layers with more than two layers and the processes for forming a silicon layer. Accordingly, processes for manufacturing a flash memory device become complicated, and the productivity may be degraded.

### SUMMARY OF THE INVENTION

The present invention provides a method for forming a non-volatile memory device capable of preventing a seam and/or a void in a floating gate.

The present invention also provides a method for forming a non-volatile memory device which simplifies the fabrication process.

According to a first aspect, the invention provides a method for forming a non-volatile memory device. According to the method, a device isolation layer is formed to define an active region on a substrate, wherein an upper portion of the device isolation layer is formed to be higher than a surface of the substrate to form a gap region surrounded by the upper portion of the device isolation layer. A tunnel insulation layer is formed on the active region, and a floating gate layer is formed on the surface of the substrate. The floating gate layer is reflowed by performing a hydrogen annealing to fill the gap region with the reflowed floating gate layer. The reflowed floating gate layer is planarized until the device isolation layer is exposed to form a floating gate pattern.

The method can further include sequentially forming a blocking insulation layer and a control gate conductive layer on a surface of the substrate and successively patterning the control gate conductive layer, the blocking insulation layer and the floating gate pattern to form a floating gate, a blocking insulation pattern and a control gate electrode, which are sequentially stacked.

The method can further include recessing the device isolation layer to expose at least a part of sidewalls of the floating gate pattern.

In one embodiment, forming the device isolation layer comprises: forming a hard mask layer on the substrate; successively patterning the hard mask layer and the substrate to form a trench defining the active region; forming a device isolating insulation layer filling the trench on the surface of the substrate; planarizing the device isolating insulation layer until the patterned hard mask layer is exposed to form the device isolation layer; and removing the patterned hard mask layer to expose the active region. A region from which the patterned hard mask layer is removed is the gap region.

In one embodiment, the floating gate layer is formed of a polysilicon layer.

In one embodiment, the blocking insulation layer is formed of an ONO layer.

In one embodiment, the blocking insulation layer is formed of a high-k dielectric layer having a high dielectric constant in comparison with a silicon nitride layer.

In one embodiment, the hydrogen annealing is performed under conditions including a process temperature ranging from 400° C. through 900° C., a process pressure ranging from 0.1 Torr through 100 Torr, a process time ranging from one minute through five hours and a hydrogen flux ranging from one sccm through 10000 sccm.

The method can further include selectively implanting impurity ions to form an impurity doping layer at the active region at both sides of the control gate electrode.

The invention provides a method for forming a non-volatile memory device comprising the following steps. A device isolation layer defining an active region is formed on a substrate. An upper portion of the device isolation layer is formed higher than a surface of the substrate to form a gap region surrounded by the upper portion of the device isolation. A tunnel insulation layer is formed on the active region, and a floating gate layer is formed on the entire surface of the substrate. The floating gate layer is reflowed by performing a hydrogen annealing to the substrate to fill the gap region with the reflowed floating gate layer. The reflowed floating gate layer is planarized until the device isolation layer is exposed to form a floating gate pattern.

In one embodiment, the method further comprises: sequentially forming a blocking insulation layer and a control gate conductive layer on an entire surface of the substrate; and successively patterning the control gate conductive layer, the blocking insulation layer and the floating gate pattern to form a floating gate, a blocking insulation pattern and a control gate electrode, which are sequentially stacked.

In some embodiments, the method further comprises recessing the device isolation layer to expose at least a part of sidewalls of the floating gate pattern.

In some embodiments, forming the device isolation may further comprise: forming a hard mask layer on a substrate and successively patterning the hard mask layer and the substrate to form a trench defining the active region. A device isolating insulation layer filling the trench is formed on the entire surface of the substrate, and the device isolating insulation layer is exposed until the patterned hard mask layer to form the device isolation layer. The patterned hard mask is removed to expose the active region. The region from which the patterned hard mask layer is removed corresponds to the gap region.

In some embodiments, the floating gate layer is formed of a polysilicon layer. The blocking insulation layer is formed of an ONO layer. Alternatively, the blocking insulation layer is formed of a high-k dielectric layer having a high constant in comparison with a silicon nitride layer.

In some embodiments, the hydrogen annealing is performed under conditions of a process temperature ranging from 400° C. to 900° C., a process pressure ranging from 0.1 Torr through 100 Torr, a process time ranging from one minute through five hours and a hydrogen flux ranging from one sccm through 10000 sccm.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1 to 4 are cross-sectional views illustrating a conventional method for forming a flash memory device.

FIGS. 5A, 6A, 7A, 8A, 9A, 10A and 11A are plan views illustrating a method for forming a non-volatile memory device in accordance with an embodiment of the present invention.

FIGS. 5B, 6B, 7B, 8B, 9B, 10B and 11B are cross-sectional views taken along a line I-I′ of FIGS. 5A, 6A, 7A, 8A, 9A, 10A and 11A, respectively.

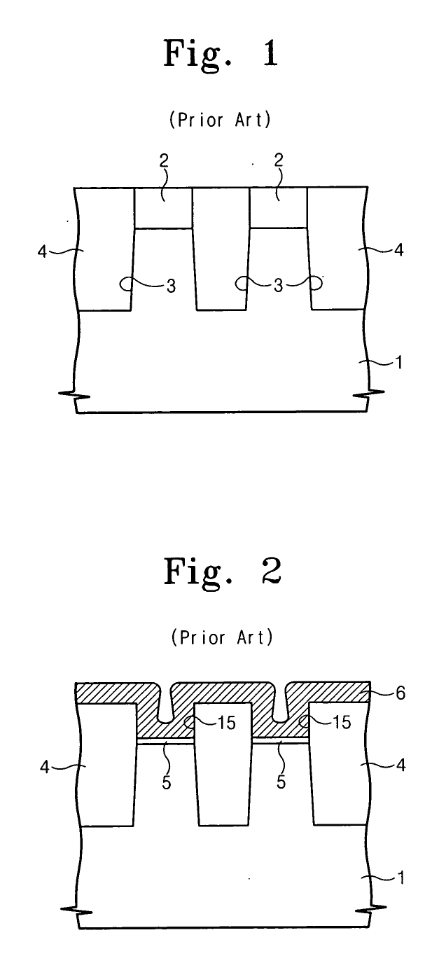

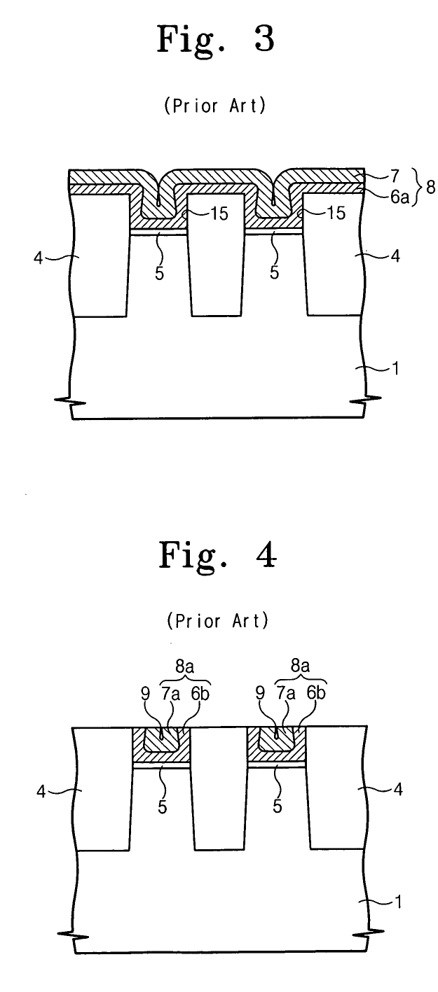

### DETAILED DESCRIPTION OF PREFERRED EMBODIMENTS

It should be noted that, herein, when a layer is described as being formed on another layer or on a substrate, the layer may be formed directly on the other layer or directly on the substrate, or a third layer may be interposed between the layer and the other layer or substrate.

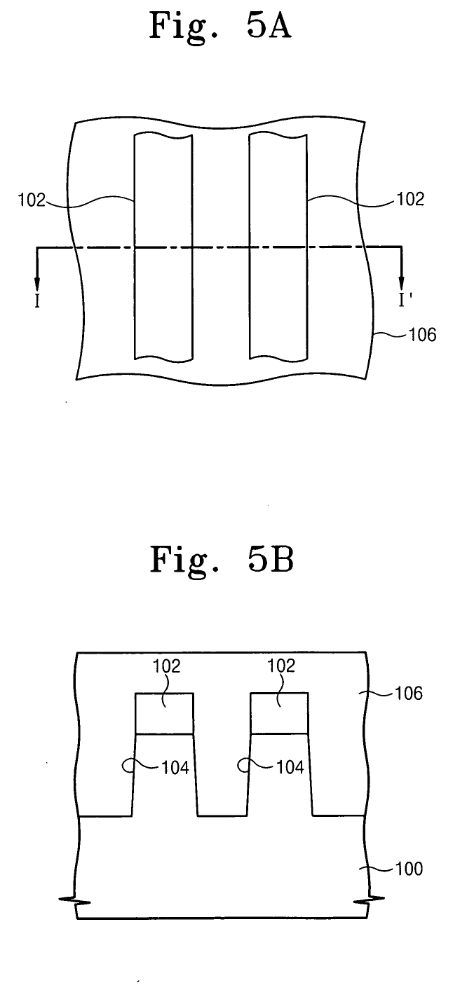

FIGS. 5A, 6A, 7A, 8A, 9A, 10A and 11A are plan views illustrating a method for forming a non-volatile memory device in accordance with a preferred embodiment of the present invention, and FIGS. 5B, 6B, 7B, 8B, 9B, 10B and 11B are cross-sectional views taken along a line I-I′ of FIGS. 5A, 6A, 7A, 8A, 9A, 10A and 11A, respectively.

Referring to FIGS. 5A and 5B, a hard mask layer is formed on the substrate 100. The hard mask layer includes a material having an etch selectivity with respect to the substrate 100, for example, a silicon nitride layer. In particular, the hard mask layer may include a buffer oxide layer and a silicon nitride layer, which are sequentially stacked. The buffer oxide layer may be formed of a silicon oxide layer.

The hard mask layer and the substrate 100 are successively patterned to form a trench 104 defining an active region. At this time, the patterned hard mask layer 102 is disposed on the active region. A device isolating insulation layer 106 filling the trench 104 is formed on an entire surface of the substrate 100. The device isolating insulation layer 106 is formed of an insulating layer with a good gap filling characteristic. For example, the device isolating insulation layer 106 may include a high density plasma silicon oxide layer and/or a SOG (Spin-On-Glass) layer.

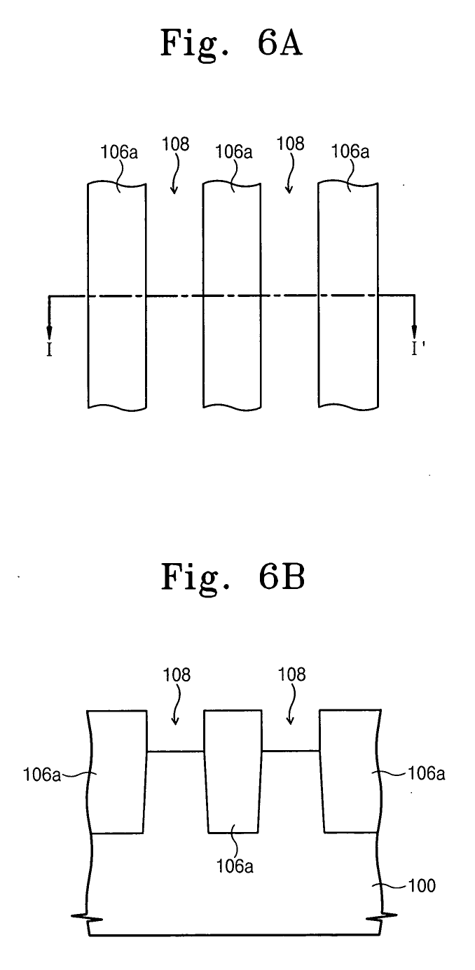

Referring to FIGS. 6A and 6B, the device isolating insulation layer 106 is planarized until the patterned hard mask layer 102 is exposed to form a device isolating layer 106a defining an active region. The device isolating layer 106a has a top surface of the same plane as the top surface of the patterned hard mask layer 102. Accordingly, a top surface of the device isolating layer 106a is formed to be higher than a surface of the substrate 100. Therefore, the device isolation layer 106a has an upper portion higher than the surface of the substrate 100.

The patterned hard mask layer 102 is removed to expose the active region. At this time, a gap region 108 from which the patterned hard mask layer 102 is removed is formed. The gap region 108 is surrounded by the upper portion of the device isolation layer 106a. The patterned hard mask layer 102 may be removed with an isotropic etching, that is, a wet etching. Accordingly, a surface of the exposed active region is prevented from being damaged by dry etching. In a case that the patterned hard mask layer 102 includes a buffer oxide layer, a surface of the upper portion of the device isolation layer 106a may be partially etched by wet etching. Due to this, a width of the gap region 108 may be increased.

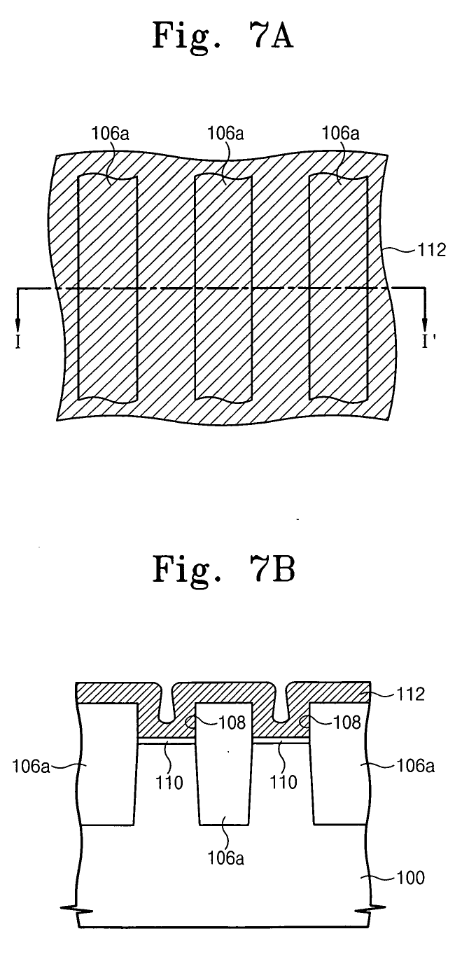

Referring to FIGS. 7A and 7B, a floating gate layer 112 is formed on an entire surface of the substrate 100. It is desirable that the floating gate layer 112 is formed of a polysilicon layer. In particular, it is desirable that the floating gate layer 112 is formed of a doped polysilicon layer using an in-situ method. The floating gate layer 112 may be formed to fill a part of the gap region 108.

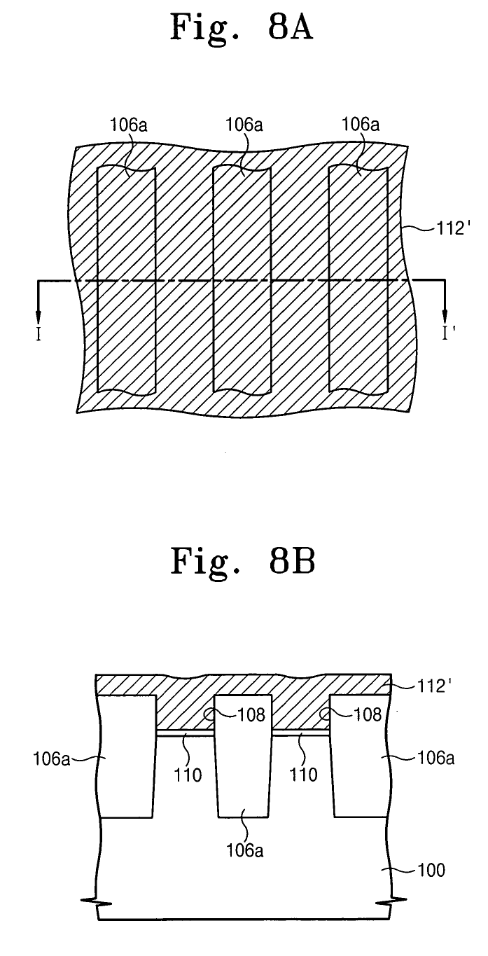

Referring to FIGS. 8A and 8B, a hydrogen annealing is performed to the substrate 100 including the floating gate layer 112. A surface energy of the floating gate layer 112 is increased by the hydrogen annealing, and silicon atoms of the floating gate layer 112 are moved so as to reduce the increased surface energy. As a result, the floating gate layer 112 is reflowed to fill the gap region 108. The reflowed floating gate layer 112′ defines a floating gate layer planarized by the hydrogen annealing.

It is preferable that the hydrogen annealing is performed at a process temperature of 400° C. through 900° C. At this time, it is preferable that the hydrogen annealing is performed under a process pressure of 0.1 Torr through 100 Torr, and a process time of one minute through five hours. It is preferable that a flux of hydrogen is 1 sccm through 10000 sccm during the hydrogen annealing.

The floating gate layer 112 is reflowed by the hydrogen annealing to completely fill the gap region 108 with the reflowed floating gate layer 112′. Accordingly, a seam and/or a void in a conventional gap region can be prevented. As a result, degradation of the characteristics of a non-volatile memory device due to the seam or the void in the conventional floating gate is prevented in the present invention. Failures of the non-volatile memory device are prevented as well.

In addition, the reflowed floating gate layer 112′ is formed with the hydrogen annealing process after a single layered floating gate layer 112 is formed. Accordingly, the method is considerably simplified in comparison with a conventional method of forming a plurality of silicon layers and performing a wet etching process between the steps of forming the silicon layers. Accordingly, a cost for manufacturing a non-volatile memory device is minimized to greatly increase its productivity.

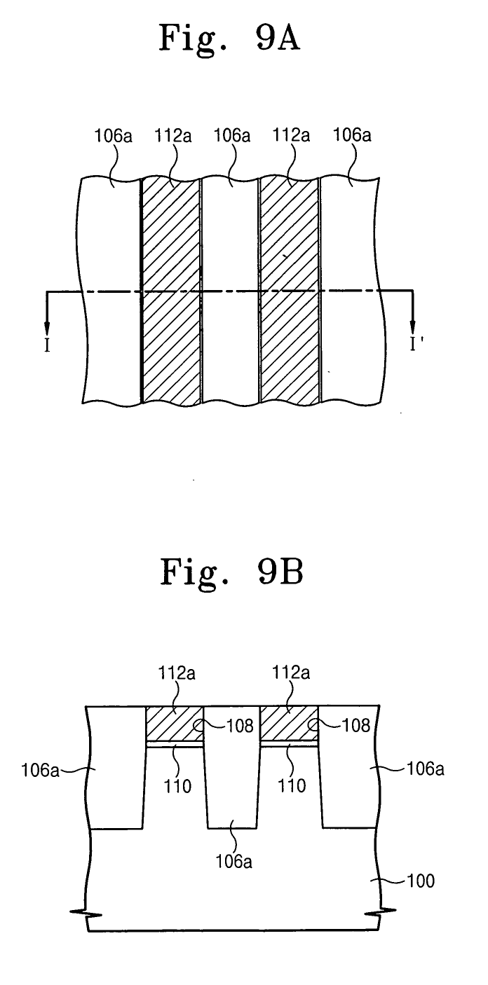

Referring to FIGS. 9A and 9B, the reflowed floating gate layer 112′ is planarized until the device isolation layer 106a is exposed to form a floating gate pattern 112a. The floating gate pattern 112a is formed using a self-alignment approach on the active region, filling the gap region 108. Therefore, the floating gate pattern 112a and the active region are freed from an overlapping problem.

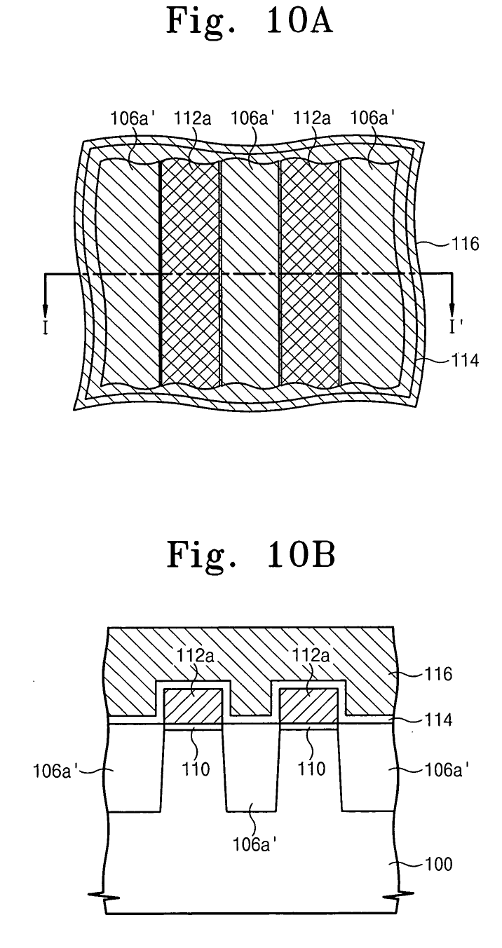

Referring to FIGS. 10A and 10B, it is preferable that the device isolation layer 106a is recessed to expose at least a part of sidewalls of the floating gate pattern 112a. It is preferable that a top surface of the recessed device isolation layer 106a′ approaches a top surface of the tunnel insulating layer 110 between the floating gate pattern 112a and the active region. That is, it is preferable that the recessed device isolation layer 106a′ exposes sidewalls of the floating gate pattern 112a to the utmost, and covers the tunnel insulating layer 110 between the floating gate pattern 112a and the active region.

A blocking insulating layer 114 is conformally formed on an entire surface of the device structure. The blocking insulating layer 114 may be formed of an ONO layer. Alternatively, the blocking insulating layer 114 can be formed of a high-k dielectric layer having a high dielectric constant in comparison with a silicon nitride layer. The blocking insulating layer 114 may be a metal oxide layer having a high dielectric constant that is made of, for example, aluminum oxide, hafnium oxide, lanthanum oxide, or combinations thereof.

A control gate conductive layer 116 covering sidewalls and a top surface of the floating gate pattern 112a is formed on the blocking insulating layer 114. The control gate conductive layer 116 is formed as a single layer or a combination layer selected from doped polysilicon, a metal, e.g., tungsten or molybdenum, metal silicide, e.g., tungsten silicide, cobalt silicide, nickel silicide or titanium silicide, and a conductive metal nitride, e.g., titanium nitride or tantalum nitride.

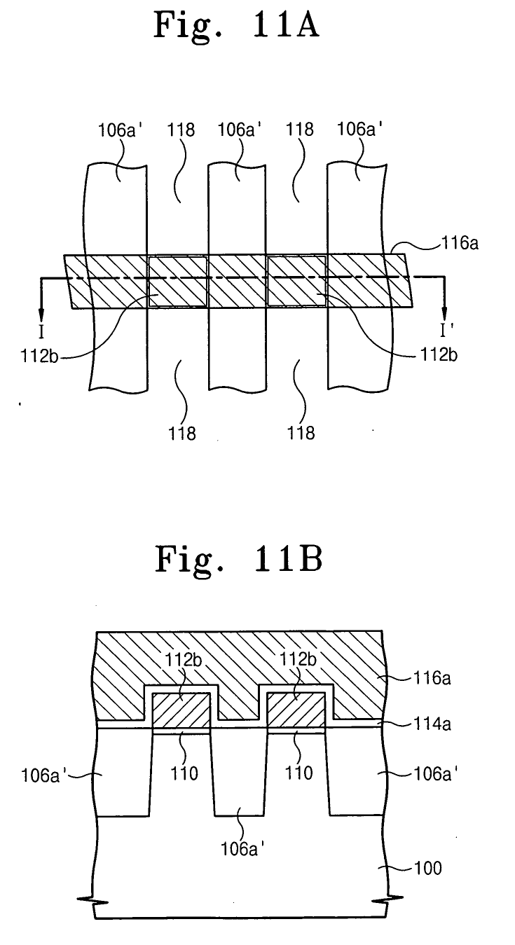

Referring to FIGS. 11A and 11B, the control gate conductive layer 116, the blocking insulating layer 114 and the floating gate pattern 112a are successively patterned to form a floating gate 112b, a blocking insulation pattern 114a and a control gate electrode 116a, which are sequentially stacked. The control gate electrode 116a crosses over the active region, and the floating gate 112b is disposed between the control gate electrode 116a and the tunnel insulting layer 110. The blocking insulating pattern 114a is interposed between the floating gate 112b and the control gate electrode 116a. The floating gate 112b is electrically insulated from the tunnel insulating layer 110 and the blocking insulating pattern 114a.

Because the sidewalls of the floating gate pattern 112a are exposed by the recessed device isolation layer 106a′, an overlapping area of the control gate electrode 116a and the floating gate 112b is increased. Accordingly, a capacitance between the control gate electrode 116a and the floating gate 112b is increased to increase a coupling ratio of a non-volatile memory cell. As a result, an operating voltage of the non-volatile memory cell drops, so that non-volatile memory device of low power consumption is realized.

Next, impurity ions are selectively implanted to form an impurity doping layer 118 on the active region at both sides of the control gate electrode 116a.

As described above, according to the present invention, a floating gate layer is reflowed by a hydrogen annealing process to fill a gap region. Accordingly, a seam or a void in a conventional floating gate pattern can be prevented. Thus, degradation of characteristics of a non-volatile memory cell and failures are prevented.

In addition, according to the present invention, the method for filling the gap region is simplified in comparison with a conventional process. As a result, a unit cost of production of a non-volatile memory device is lowered to greatly increase its productivity.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method for forming a non-volatile memory device, comprising:
forming a device isolation layer to define an active region on a substrate, wherein an upper portion of the device isolation layer is formed to be higher than a surface of the substrate to form a gap region surrounded by the upper portion of the device isolation layer;
forming a tunnel insulation layer on the active region;
forming a floating gate layer on the surface of the substrate;
reflowing the floating gate layer by performing a hydrogen annealing to fill the gap region with the reflowed floating gate layer; and
planarizing the reflowed floating gate layer until the device isolation layer is exposed to form a floating gate pattern.

2. The method of claim 1, further comprising:
sequentially forming a blocking insulation layer and a control gate conductive layer on a surface of the substrate; and
successively patterning the control gate conductive layer, the blocking insulation layer and the floating gate pattern to form a floating gate, a blocking insulation pattern and a control gate electrode, which are sequentially stacked.

3. The method of claim 1, further comprising recessing the device isolation layer to expose at least a part of sidewalls of the floating gate pattern.

4. The method of claim 1, wherein forming the device isolation layer comprises:
forming a hard mask layer on the substrate;
successively patterning the hard mask layer and the substrate to form a trench defining the active region;
forming a device isolating insulation layer filling the trench on the surface of the substrate;
planarizing the device isolating insulation layer until the patterned hard mask layer is exposed to form the device isolation layer; and
removing the patterned hard mask layer to expose the active region,
wherein a region from which the patterned hard mask layer is removed is the gap region.

5. The method of claim 1, wherein the floating gate layer is formed of a polysilicon layer.

6. The method of claim 1, wherein the blocking insulation layer is formed of an ONO layer.

7. The method of claim 1, wherein the blocking insulation layer is formed of a high-k dielectric layer having a high dielectric constant in comparison with a silicon nitride layer.

8. The method of claim 1, wherein the hydrogen annealing is performed under conditions including a process temperature ranging from 400° C. through 900° C., a process pressure ranging from 0.1 Torr through 100 Torr, a process time ranging from one minute through five hours and a hydrogen flux ranging from one sccm through 10000 sccm.

9. The method of claim 1, further comprising selectively implanting impurity ions to form an impurity doping layer at the active region at both sides of the control gate electrode.
